(19) United States
(12) Patent Application Publication
(10) Pub. No.: US 2013/0243208 A1
(43) Pub. Date: Sep. 19, 2013

(54) COMPUTER USER ALERTNESS MONITORING SYSTEM

(71) Applicant: Mark S. Fawer, New York, NY (US)

(72) Inventor: Mark S. Fawer, New York, NY (US)

(21) Appl. No.: 13/423,362

(22) Filed: Mar. 19, 2012

(51) Int. Cl. H03G 3/20; G09G 5/00; G08B 23/00

(52) U.S. Cl. 381/57; 340/573.1; 345/156

(57) ABSTRACT

The invention relates to computer based user alertness monitoring systems for detecting and alleviating user fatigue. A computer-implemented automated system and method for detecting and reducing user fatigue is provided. The invention detects user alertness based on user dexterity using computer input devices and remedies a fatigued state by implementing visual, tactile and/or aural stimuli. Compensation mechanisms for increased ambient temperature and noisy environments are also presented.

The present invention relates to computer based user alertness monitoring systems for detecting and alleviating user fatigue. The invention detects user awareness based on user dexterity using computer input devices and implements remedial action by visual, aural and/or tactile stimuli.

### BACKGROUND OF THE INVENTION

The pervasiveness of computer-human information exchange in daily business practice has led to increased efficiencies in information gathering and communication. Workers spend hours interacting with computers using input devices such as keyboards and computer mice and viewing information output on computer displays using cathode ray tube (CRT), light emitting diode (LED), and liquid crystal display (LCD) technologies. Cognitive and visual fatigue resulting from repetitive task execution and long hours of viewing electronic displays is well known and impacts on efficiency, and safety have been discussed. According to OSHA Publication 3092, 1997 (Revised), the National Institute for Occupational Safety and Health (NIOSH) recommends a 10-minute rest break after two hours of continuous Video Display Terminal (VDT) work for users under moderate visual demands; and a 15 minute rest break after one hour of continuous VDT work where there is a high visual demand or repetitive work task.

In an effort to detect and manage the impact of cognitive and eye fatigue, various devices and methods of detection and control have been proposed. U.S. Pat. No. 6,346,887 cites several studies that link a state of drowsiness to eye pupil diameter and eyelid droop. The patented device measures and evaluates eye activity based on pupil diameter and position, visual fixation frequency and duration, and blink frequency, and applies them to alertness models to determine onset of user fatigue or drowsiness in real-time.

Other patents claim that fixed-plane focus results in eye-strain that can be relieved by periodic use of eye exercises where the user focuses on 3-dimensional images or lights placed in multiple planes of focus. U.S. Pat. No. 6,139,149 claims a 3-dimensional “air sculpture” that relieves eyestrain by allowing a user to focus attention on the sculpture. U.S. Pat. No. 5,515,069 allows the user to exercise the eyes by periodically following a series of lights placed at various positions in 3-dimensional space.

Still other patents describe eye-fatigue as a function of continuous viewing of images on a display and claim means to reduce the fatigue by altering the characteristics of the displayed image. U.S. Pat. No. 5,933,130 describes an apparatus and method for automatic computer-controlled adjustment of video display brightness, contrast, and color so as to avoid eye-strain. Separately, U.S. Pat. No. 5,528,268 describes an automatic method for slowly adjusting video display horizontal and vertical size, brightness and contrast so as to reduce eye-strain. U.S. Pat. No. 5,450,138 describes CRT flicker as a contributing factor to eye-strain and claims a display monitor that corrects flicker in video images.

The described prior-art references, however, do not examine manual task performance as a tool for detection of cognitive and visual fatigue. One such tool would examine degradation in proficiency at entering data using a keyboard, touch screen, joystick and/or mouse as an indicator of user fatigue.

The present invention provides a system and methodology for evaluating cognitive and eye fatigue based on performance-based feedback between a user and the evaluation system.

It is advantageous to provide methods and apparatus that detect degrading performance and quickly alert a user of the situation. Under certain circumstances, a degradation in performance could be life-threatening. Air-traffic control is one example of a situation where a drowsing worker might delay transmission of vital air traffic safety information to pilots, potentially threatening the lives of passengers.

The present invention provides methods and apparatus having the aforementioned and other advantages. Moreover, the unique combination of components/techniques disclosed herein provides various improvements over previously known structures and techniques.

### SUMMARY OF THE INVENTION

A computer-implemented automated system for detecting and reducing user fatigue is provided. The system includes at least one processor, at least one data storage unit for storing a set of programming instructions and user performance metric information, at least one information input device, at least one information output device, at least one communication channel connecting the processor and the data storage unit, at least one communication channel connecting the processor and at least one information input device, and at least one communication channel connecting the processor and at least one information output device. The computer-implemented automated system evaluates user fatigue based on the set of programming instructions and the user performance metric information.

The input devices include a keyboard, a computer mouse, a computer attached joystick device, a touch screen device, or any other suitable input device. The output devices include a loudspeaker, a headphone, a transducer (e.g., a piezoelectric transducer for providing a tactile signal such as vibrating a user's chair or the like), a cathode ray tube video display, a liquid crystal display, a light emitting diode display, a plasma display, or any other suitable output device.

Also provided is a method for detecting user fatigue including the steps of specifying a nominal user performance metric for an input device, and storing the nominal user performance metric in a data storage metric. In accordance with the method, a user performance of the input device can be monitored in real-time. The nominal user performance is compared with the real-time user performance of the input device. The user is alerted if the real-time performance is less than the nominal performance using the input device. A real-time user performance less than the nominal user performance indicates user fatigue.

The input devices include, e.g., a keyboard, a computer mouse, a computer attached joystick device or a touch screen device. The nominal and real-time user performance metric includes one of either the number of keystrokes typed on a keyboard per time period, the number of touches on a touch screen per time period, the number of movement cycles of a computer mouse per time period, the number of switch activations on a computer mouse per time period, the number of movement cycles of a joystick device per time period, or the number of switch activations of a joystick device per time period. A single movement cycle comprises a reposition of a device from a beginning stationary position in a 3-dimensional space and passing through at least one different location in a 3-dimensional space and ending at a stationary position in an ending 3-dimensional space.

The included output devices may be a loudspeaker, a headphone, a transducer, a cathode ray tube video display, a liquid crystal display, a light emitting diode display, or a plasma display.

Alerting the user of fatigue involves at least one of audio signal communication or a visual, e.g., video signal communication. The audio signal communication includes either emitting an audible sound for a predetermined duration, or increasing output volume of already operational audio signals for a predetermined duration. The video signal communication includes selecting and displaying for a predetermined duration, an alternative video display resolution chosen from a group of compatible resolutions. Alternatively, the video signal communication includes selecting and displaying for a predetermined duration, a moving or stationary banner image. The alert is prematurely terminated by human induced deactivation.

The audio signal communication is adjusted by performing the steps of measuring a nominal ambient noise volume level for a user environment using a sound level measuring device; and increasing the audio volume of the audio signal communication by the nominal ambient noise volume level. The sound level measuring device is either a sound level meter, or a microphone enabled with programming instructions for measuring sound level.

Also, the nominal user performance metric of the method of detecting user fatigue is adjusted by an ambient temperature offset value, where said ambient temperature offset value is calculated from a temperature measurement using a temperature sensing device. The temperature sensing device is a thermometer enabled to communicate with temperature recording software on a computer.

### BRIEF DESCRIPTION OF THE DRAWINGS

FIG. 1 is a block diagram of the key components of the Automated Visual/Audio monitoring system.

FIG. 2 is a flow diagram illustrating administrator selectable input parameters.

FIG. 3 is a flow diagram illustrating administrator selectable output and alert parameters.

FIG. 4 is a flowchart indicating process decisions evaluated in detecting user fatigue and implementing remedial action.

### DETAILED DESCRIPTION OF THE INVENTION

The present invention detects and remedies computer user fatigue by automatically assessing the state of user awareness based on a user's dexterity while performing computer-related tasks. These tasks include keyboard or touch screen data entry, mouse movement, mouse button activation (“clicking”), joystick movement, and joystick button activation. A nominal state of user performance while executing these tasks is predetermined, supplying a metric against which real-time performance can be judged. This metric is stored in computer system memory, to be accessed and compared with real-time performance of these tasks. Performance below nominal infers a reduced state of user awareness, to which the system responds by initiating remedial action by presenting the user with visual, aural and/or tactile stimuli to wake the user.

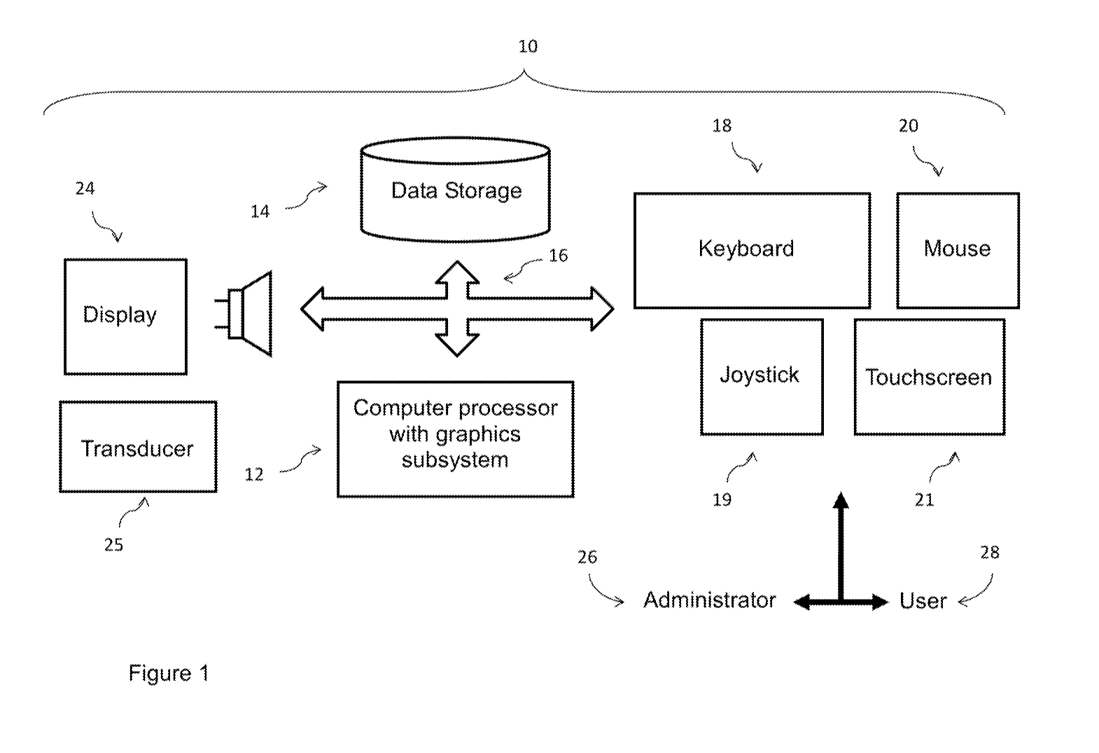

FIG. 1 illustrates a computer system 10 that contains a computer processor with a graphics subsystem 12. A data storage memory 14 stores programming instructions, and data used to evaluate a user's level of performance. The system 10 initiates programs that elicit sounds and graphics to wake the user in response to degradation in user performance as a result of cognitive or eye-strain fatigue. Data needed for program execution is routed to computer processor 10 through communications channel 16. While a single processor system is shown in FIG. 1, multiprocessor systems are also supported. System administrator 26 preloads the system with default metrics that are compared with real-time user 28 performance.

On a continual basis, for example, under a multitasking computing environment, the processor 10 analyzes the frequency of data input received from peripheral devices, for example, from a keyboard 18, a joystick 19, a computer mouse 20, a touch screen 21 (e.g., on a monitor or tablet computer), or the like for degradation in user 28 performance. It should be appreciated that other input devices that may be developed in the future may also be analyzed and used as the basis for evaluating a user's level of performance in accordance with the invention. The system 10 responds to sufficient degradation to indicate user fatigue by alerting the user by synthesizing changes to video and audio signals that are routed back through communications channel 16 to output devices such as a loudspeaker (or headphone) 22 and a video display 24. Example video displays include Cathode Ray Tube (CRT), Light Emitting Diode (LED), Liquid Crystal Display (LCD), or plasma screen displays. A transducer 25 can also be provided to provide tactile feedback.

The automated performance analysis is executed while users 28 perform ordinary tasks while interfacing with input devices such as a keyboard 18, joystick 19, a computer mouse 20, a touch screen 21, and the like. The system continuously monitors the user's performance in real-time, and the user 28 receives feedback from the computer system 10 through output devices such as loudspeakers 22, video displays 24 and/or transducer 25 only when fatigue is suspected.

The frequency of data input into the system is determined by number of movement cycles (“movement”) of an input device or alternatively the activation of switches on the input device. A movement cycle of a device is defined by a single cycle of a reposition of a device from a beginning stationary position in a 3-dimensional space and passing through at least one different location in a 3-dimensional space and ending at a stationary position in an ending 3-dimensional space. The beginning and ending position in space may be the same. For example, a movement of a joystick, while beginning and ending at the approximate same position in space passes through at least one other location in space.

The present invention responds to detected user fatigue by alerting the user by aural, visual and/or tactile stimuli. Such an alert is expressed by initiating an aural, visual or tactile software routine. One example embodiment visual software routine changes viewing characteristics of the display, specifically the resolution settings. The software routine may be written in a higher-level programming language whereby logical device driver instructions are communicated to a physical device driver that controls display hardware directly.

Furthermore, ambient noise levels influence the volume of the synthesized aural stimuli that is introduced by the system to effectively be noticed by the user. A lower ambient noise level requires a relatively low aural alert volume, while a higher ambient noise level requires a relatively high aural alert volume so as to be noticed above the ambient noise. A fatigue detection system adapted to extract ambient noise levels from the environment includes a microphone equipped computer with noise level metering software specifically adapted to monitor room noise levels in real-time. Real-time ambient noise levels are compared against a predetermined metric, such that a relative volume over background noise is maintained.

In conjunction with the fatigue assessment based on dexterity, applicant suggests that ambient room temperature has a directly proportional affect on user fatigue. Applicant believes that a soporific effect occurs with rising temperature, leading to onset of user fatigue at a lower threshold than is indicated by a metric that was specified at a lower ambient temperature. As a result, applicant anticipates the need to implement an offset to compensate for this effect implemented during administrator setup or calibration of the system. Ambient temperature is assessed by an administrator and entered into a system on system initialization or alternatively, a temperature sensing device such as a thermometer is connected to a computer to allow automated temperature recording via computer software.

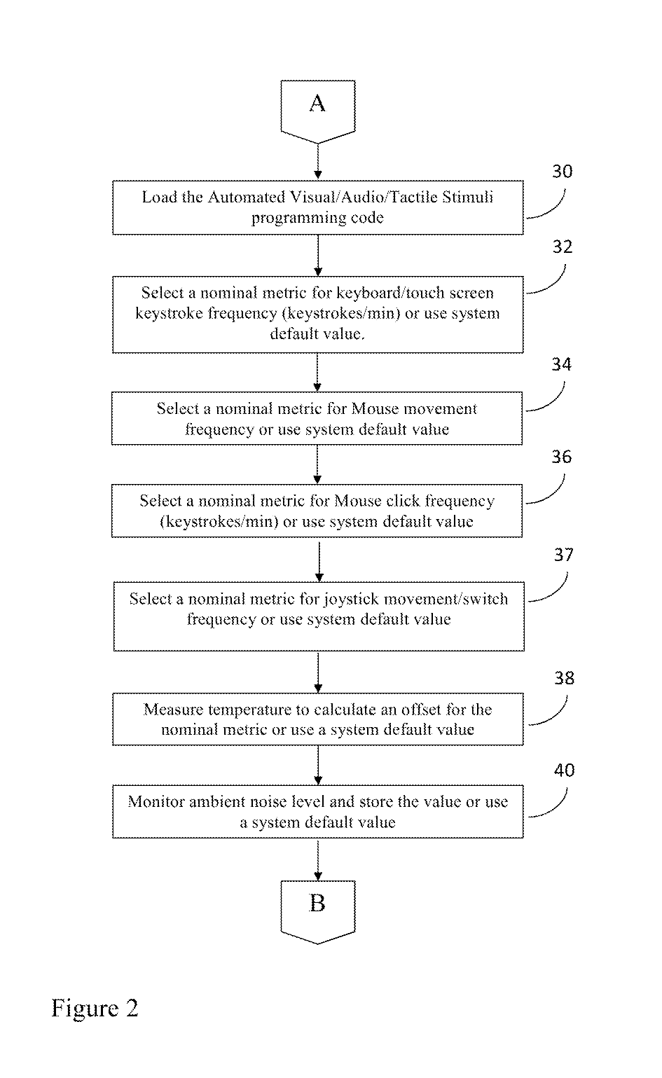

FIG. 2 illustrates the steps for initialization of input parameters that the system uses to assess user fatigue. The task of initialization begins at box “A” and is typically performed by a system administrator. The Automated Visual/Audio Stimuli programming code is initially loaded 30 into data storage memory 14 of the computer system 10. For each user 28 of the system, a nominal keystroke and/or touch frequency (e.g. keystrokes or touch screen touches per minute) is recorded 32 in data storage memory 14, as a metric to be accessed as needed for comparison with real-time keystroke or touch frequency data. Alternatively, a system default value for keystroke or touch frequency may be used for comparison purposes 32. Similarly, for each user 28 of the system, a nominal mouse movement frequency metric 34 (e.g. mouse movements per minute) is stored in data storage memory 14, to be accessed for comparison with real-time mouse movement frequency data. Nominal mouse button activation (“click”) frequency 36 (e.g. mouse clicks per minute) and joystick movement/switch frequency 37 are also recorded in data storage memory 14 as metrics. For a particular user 28, each type of input device receives a nominal value that may be obtained from testing, prior real-time experience with that particular user's performance, from all users averaged performance data, or by any other means available to a system administrator 26 in assessing the metric.

Additionally, ambient temperature 38 is measured and stored in data storage memory 14, or alternatively, a default value may be supplied by the administrator 26. An offset value based on the ambient temperature is applied against the metric assigned for each input device type. This offset value is determined by empirical study of user 28 performance in particular ambient temperatures, or a default value may be assigned. The offset acts to change the condition at which aural, visual and/or tactile stimuli is initiated.

Ambient noise level 40 is measured in real-time, stored, and periodically updated in data storage memory 14. The metric is accessed when the system determines that an audio alert is needed to stimulate the user 28. Alternatively, the administrator 26 can enter a default value for the noise level or the system can use real-time noise level measurement data.

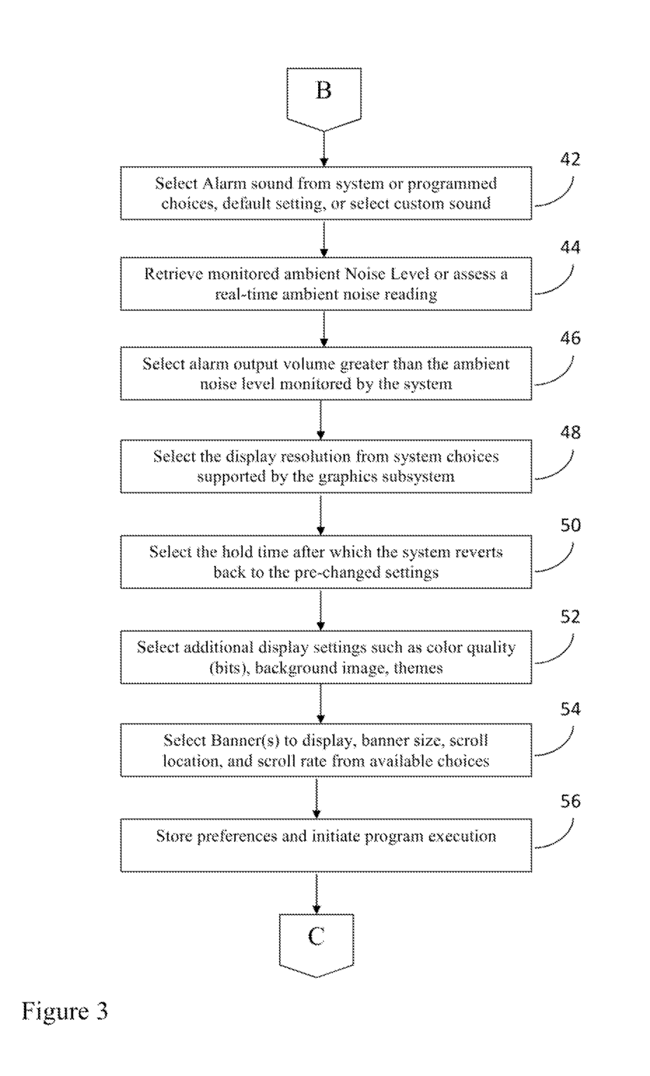

Output parameter initialization is shown in FIG. 3 and begins at box “B”. In a first example embodiment, a typical system alert response to user 28 fatigue is to sound an alarm or change video resolution. An administrator 26 initially selects an alarm sound from the system or software menu or alternatively, a custom sound can be supplied 42. An alarm volume level greater than the ambient noise is necessary to be heard above ambient noise. A real-time or stored ambient noise metric is recalled from memory 44 and compared with the ambient noise. A volume is selected that is sufficiently loud to be clearly heard by the user 46, preferably loud enough to awaken a fatigued user 28.

Applicant asserts that a change in display resolution in lieu of, or in addition to an audio alarm, or tactile feedback awakens a fatigued user. The choice of display resolution is a function of the type of graphics subsystem 12 as well as the display 24 type. It is the choice of the system administrator 26 to select a suitable display resolution and other optional display settings 48. After a suitable period of time, the display reverts back to the former state (resolution and display settings prior to the change), since a consequence of a resolution change is an alteration in the viewable image area displayed. It is the administrator that selects the time period for reversion to the former state 50. Alternatively, the resolution will not revert back to the former state. Additional changes to display settings upon activation of an alert can also be specified. These changes include, for example, changes to color quality (color depth (bits per pixel)), and background image or background themes, whether moving or still 52. Moving or still banner and pop-up images 54 with custom messages such as “WAKE UP!” or “TAKE A BREAK!” can be displayed, however the administrator 26 is responsible for programming these messages at system initialization. After preference selection and storage, program execution is initiated 56 and the system is ready for ordinary use by a user 28.

After system initialization, the program waits for a user 28 to log onto the system, and awaits an event trigger. Example event triggers include keystroke action, touch screen action, mouse click action, mouse movement, joystick click action, or joystick movement. The program continuously checks the frequency of such actions against the stored nominal metrics established by the administrator 26.

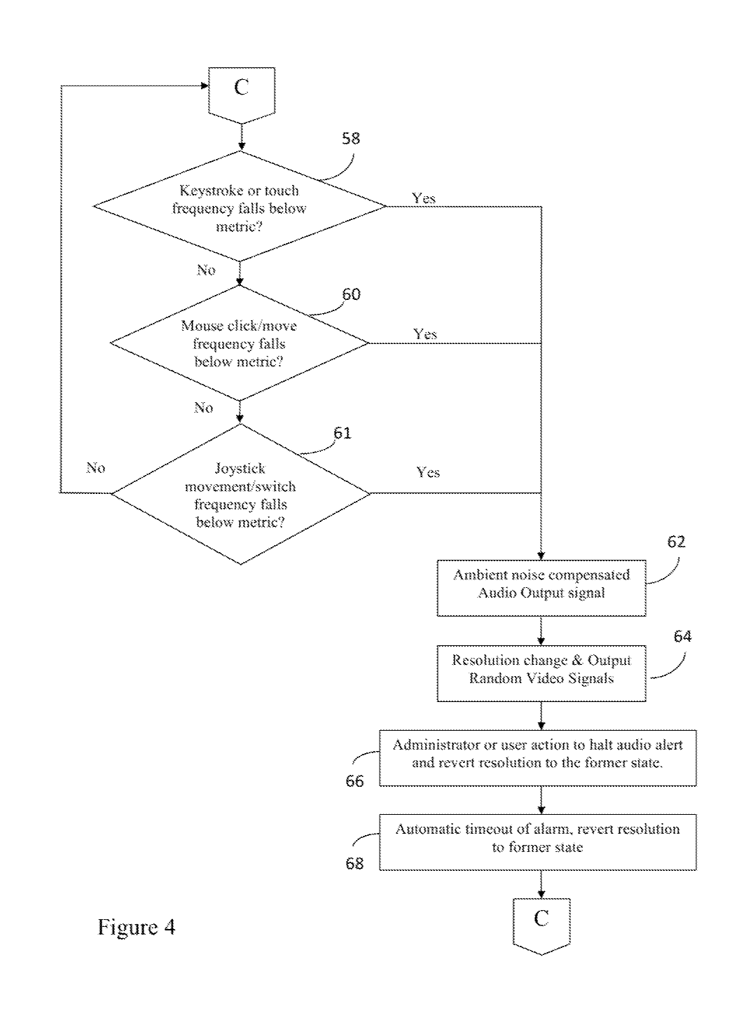

FIG. 4 shows one embodiment of such a system that continually checks if a user entered keystroke or touch frequency (keystrokes or touches per minute) 58, mouse click or movement frequency 60, or joystick movement/switch frequency 61 has fallen below a nominal metric. If the frequency has fallen below the metric, an audio and/or visual alert is initiated. If an audio alert is specified for the event, the ambient noise level is recalled from memory 14 and the output volume level is adjusted to compensate for the ambient noise 62. If a visual (e.g., video) alert is specified for the event, the resolution is changed and random video signals are output to the display 64. Administrator 26 or user 28 action can halt the audio alert and revert display resolution to the former state 66. Alternatively, an automatic timeout can be programmed to end the alert after a predetermined period of time, thereby stopping the audio alarm and reverting display resolution to the former state 68. The system thereafter continues to monitor future events, Box “C”.

Although the invention has been described in accordance with particular example embodiments, those skilled in the art will appreciate that various other embodiments, variations and modifications can be provided using the teachings of the invention, all of which are intended to be included within the scope of the following claims.

What is claimed is:

1. A computer-implemented automated system for detecting and reducing user fatigue comprising:
at least one processor;
at least one data storage memory for storing a set of programming instructions and user performance metric information;
at least one information input device;
at least one information output device;
at least one communication channel connecting said processor and said data storage memory;
at least one communication channel connecting said processor and said at least one information input device;
at least one communication channel connecting said processor and said at least one information output device;
wherein said computer-implemented automated system evaluates user fatigue based on said set of programming instructions and said user performance metric information.

2. A system in accordance with claim 1, wherein said input device comprises a keyboard, a computer mouse, a joystick device or a touch screen device.

3. A system in accordance with claim 1, wherein said output device comprises at least one of a loudspeaker, a headphone, a transducer or a visual display.

4. A method for detecting user fatigue comprising:
specifying a nominal user performance metric for an input device;
storing said nominal user performance metric in a data storage memory;
monitoring a real-time user performance of said input device;
comparing said nominal user performance with said real-time user performance of said input device; and
alerting said user if said real-time performance is less than said nominal performance of said input device;
wherein said real-time user performance less than said nominal user performance indicates user fatigue.

5. A method in accordance with claim 4, wherein said input device comprises a keyboard, a computer mouse, a joystick device, or a touch screen device.

6. A method in accordance with claim 4 wherein said nominal and real-time user performance metric comprises at least one of:
a number of keystrokes typed on a keyboard per time period,
a number of touches on a touch screen per time period,
a number of movement cycles of a computer mouse per time period,
a number of switch activations on a computer mouse per time period,
a number of movement cycles of a joystick device per time period,
a number of switch activations of a joystick device per time period, wherein a single movement cycle comprises a reposition from a beginning stationary position in a 3-dimensional space and passing through at least one different location in a 3-dimensional space and ending at a stationary position in an ending 3-dimensional space.

7. A method in accordance with claim 4, wherein said output device comprises at least one of a loudspeaker, a headphone, a transducer or a visual display.

8. A method in accordance with claim 4 wherein said alerting comprises at least one of audio signal communication, a tactile signal communication, or visual signal communication.

9. A method in accordance with claim 8 wherein said audio signal communication comprises at least one of:
emitting an audible sound for a predetermined duration, or
increasing output volume of already operational audio signals for a predetermined duration.

10. A method in accordance with claim 8 wherein said visual signal communication comprises selecting and displaying for a predetermined duration, an alternative video display resolution chosen from a group of compatible resolutions.

11. A method in accordance with claim 8 wherein said visual signal communication comprises selecting and displaying for a predetermined duration, a moving or stationary banner image.

12. A method in accordance with claim 4 wherein said alerting is prematurely terminated by human induced deactivation.

13. A method in accordance with claim 8, wherein said audio signal communication is adjusted by:
measuring a nominal ambient noise volume level for a user environment using a sound level measuring device; and
increasing the audio volume of said audio signal communication by said nominal ambient noise volume level.

14. A method in accordance with claim 13, wherein said sound level measuring device comprises one of a sound level meter, or a microphone enabled with programming instructions for measuring sound level.

15. A method in accordance with claim 4 wherein:
said nominal user performance metric is adjusted by an ambient temperature offset value calculated from a temperature measurement using a temperature sensing device.

16. A method in accordance with claim 15, wherein said temperature sensing device comprises a thermometer enabled to communicate with temperature recording software on a computer.
